(19) United States
(12) Patent Application Publication
(10) Pub. No.: US 2007/0170586 A1
(43) Pub. Date: Jul. 26, 2007

(54) Printed circuit board for semiconductor package and method of manufacturing the same

(75) Inventors: Yong Bin Lee, Chungcheongbuk-do (KR); Kyoung Won Bae, Gyeonggi-do (KR); Jong Min Choi, Chungcheongbuk-do (KR); Eui Youn Yoo, Gyeonggi-do (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD, Suwon-si (KR)

(21) Appl. No.: 11/646,552

(22) Filed: Dec. 28, 2006

(30) Foreign Application Priority Data
Jan. 23, 2006 (KR) 10-2006-0006854

(51) Int. Cl. H01L 23/48

(52) U.S. Cl. 257/737

(57) ABSTRACT

Disclosed are a printed circuit board for a semiconductor package and a method of manufacturing the same. Specifically, a printed circuit board for a semiconductor package includes predetermined circuit patterns, having a wire bonding portion and a bump portion for mounting a semiconductor and a soldering portion for connection to external parts, in which the bump portion has a pre-solder formed using a tin or tin alloy electroplating process. According to this invention, the pre-solder, which is formed by reflow using an electroplating process, permits easy increase of the height thereof to thus enhance bondability and underfilling capability, may be formed to a desired thickness by controlling a plating thickness, and furthermore, may be applied to a fine pitch through a masking process.

### CROSS REFERENCE TO RELATED APPLICATION(S)

This application claims the benefit of Korean Patent Application No. 10-2006-0006854, entitled “Method for manufacturing printed circuit board for semi-conductor package and printed circuit board manufactured therefrom”, filed Jan. 23, 2006, which is hereby incorporated by reference in its entirety into this application.

### BACKGROUND OF THE INVENTION

1. Field of the Invention

The present invention relates, in general, to a printed circuit board (PCB) for a semiconductor package and a method of manufacturing the same. More particularly, the present invention relates to a PCB for a semiconductor package, in which a pre-solder can be formed on a bump portion using a tin or tin alloy electroplating process to thus enhance bondability and underfilling capability, and can be formed to a desired thickness by controlling a plating thickness, and in which it is possible to realize fine pitch, and to a method of manufacturing the same.

2. Description of the Related Art

With an increase in the degree of integration of IC packages, the packaging industry has evolved from dual in-line packages (DIPs) to quad flat packages (QFPs), ball grid arrays (BGAs), chip scale packages (CSPs), and flip chip packages, each having a high lead density. Such a change in packages is regarded as the best in satisfying the requirement for miniaturization and light weight of final PCB assemblies, and is thus rapidly occurring.

For die attachment, a wire bonding process using Au wires has been conventionally applied to date, however, flip chip technology, capable of fulfilling the requirement for low profiles and high speed, is mainly used at present in place thereof.

As shown in FIG. 1, conventional flip chip mounting technology is focused on a bumping process using a solder 12 formed on a bump portion 11 of a wafer 10, that is, a chip die 10, and also discloses the solder 12 after the bump portion 11 of the die 10 is attached to a bump portion 21 of a PCB 20 (U.S. Pat. Nos. 6,642,079, 6,744,142, and 6,877,653). In addition, with reference to FIG. 2, in order to attach a die 10 to a PCB 20 in a flip chip-chip size package (FCCSP), a pre-solder 22 may be formed on a bump portion 21 of the PCB 20, which is able to adhere to the die 10 in order to increase the adhesion to the bump portion 11 of the die 10 and reliability thereof.

The flip chip technology is classified into an area array type and a peripheral array type, depending on a chip design method. Of these, the peripheral array type does not need a redistribution layer (RDL), which has been provided in a conventional wire bonding process. However, in the case where the RDL should be formed for conversion into the array type, circuit interference occurs due to the formation of narrow circuits, undesirably increasing the noise generation rate. Thereby, there is a need for verification through simulation and performance tests, resulting in a long time period for completing a final design. Therefore, in the peripheral type shown in FIG. 3, an Au stud bump 32 is formed on a bump portion 31 of a die 30 using a conventional wire bonding machine. In addition, as in FIG. 4, for the attachment of a die 30 to a PCB 40 in FCCSP, a pre-solder 42 may be formed on a bump portion 41 of the PCB 40 which is able to adhere to the die 30 to increase adhesion to an Au stud bump 32 of the die 30 and reliability thereof.

In this way, examples of conventional techniques for forming the pre-solder on the bump portion of the PCB include a screen printing method, a super solder method, and a super juffit method.

Of these methods, in the super juffit method, the flowchart and cross-sectional views sequentially illustrating the process of forming a pre-solder on the surface of the substrate for a package to be soldered to the die are shown in FIGS. 5A and 5B, respectively.

With reference to FIGS. 5A and 5B, the surface of a bump portion 51 of a PCB, that is, the surface of a copper layer 51, which is exposed through an opening process using a solder mask 50, is subjected to soft etching and then chemical treatment to thus form a predetermined level of roughness, after which the formation of an adhesive layer 52, the application of solder powder 53, and the application of a flux 54 are performed, and then a reflow process and a washing process are carried out, thus forming a pre-solder 55. In addition, after the application of the solder powder, a reflow process and a cleaning process may be further performed for fixing, if necessary.

However, in the conventional pre-solder formation techniques, the screen printing method suffers because it is difficult to realize a pre-solder of 120 μm pitch or less. In addition, although the super juffit method and the super solder method may be applied even to a fine pitch of 100 μm pitch or less, they incur high costs. Accordingly, there are urgently required process techniques capable of inexpensively manufacturing a PCB for a package able to realize a fine pitch using a pre-solder formation process.

### SUMMARY OF THE INVENTION

Leading to the present invention, intensive and thorough research into PCBs for packages, carried out by the present inventors aiming to avoid the problems encountered in the related art, resulted in the finding that a pre-solder may be formed on the bump of a PCB using a tin or tin alloy electroplating process, thereby inexpensively manufacturing a PCB for a package able to realize a fine pitch.

Therefore, one aspect of the present invention is to provide a PCB for a semiconductor package and a manufacturing method thereof, in which a fine pitch may be realized through an economical process.

Another aspect of the present invention is to provide a PCB for a semiconductor package and a manufacturing method thereof, in which it is easy to increase the height of a pre-solder to thus enhance bondability and underfilling capability.

A further aspect of the present invention is to provide a PCB for a semiconductor package and a manufacturing method thereof, in which a pre-solder may be formed to a desired height by controlling a plating thickness.

According to a first aspect of the present invention, the present invention provides a PCB for a package with predetermined circuit patterns, having a wire bonding portion and a bump portion for mounting a semiconductor and a soldering portion for connection to external parts; wherein at least the bump portion among the wire bonding portion, the bump portion and the soldering portion includes a copper or copper alloy layer; and a tin or tin alloy electroplating layer formed on the copper or copper alloy layer.

According to a second aspect of the present invention, the present invention provides a PCB for a package with predetermined circuit patterns, having a wire bonding portion and a bump portion for mounting a semiconductor and a soldering portion for connection to external parts; wherein the wire bonding portion, the bump portion and the soldering portion include a copper or copper alloy layer; and a tin or tin alloy electroplating layer formed on the copper or copper alloy layer.

According to a third aspect of the present invention, the present invention provides a PCB for a package with predetermined circuit patterns, having a wire bonding portion and a bump portion for mounting a semiconductor and a soldering portion for connection to external parts, wherein the wire bonding portion and the soldering portion include a copper or copper alloy layer, a nickel or nickel alloy electroplating layer formed on the copper or copper alloy layer, and a gold or gold alloy electroplating layer formed on the nickel or nickel alloy electroplating layer; and the bump portion includes a copper or copper alloy layer, and a tin or tin alloy electroplating layer formed on the copper or copper alloy layer.

According to a fourth aspect of the present invention, the present invention provides a PCB for a package with predetermined circuit patterns, having a wire bonding portion and a bump portion for mounting a semiconductor and a soldering portion for connection to external parts, wherein the wire bonding portion and the soldering portion include a copper or copper alloy layer, a nickel or nickel alloy electroplating layer formed on the copper or copper alloy layer, and a gold or gold alloy electroplating layer formed on the nickel or nickel alloy electroplating layer; and the bump portion includes a copper or copper alloy layer, a nickel or nickel alloy electroplating layer formed on the copper or copper alloy layer, a gold or gold alloy electroplating layer formed on the nickel or nickel alloy electroplating layer, and a tin or tin alloy electroplating layer formed on the gold or gold alloy electroplating layer.

As such, the tin alloy electroplating layer preferably comprises tin (Sn) and any one selected from among silver (Ag), copper (Cu), zinc (Zn), bismuth (Bi), and combinations thereof.

More preferably, the tin alloy electroplating layer comprises Sn—Ag, Sn—Cu, Sn—Zn, or Sn—Bi, in which Ag, Cu, Zn and Bi may be used in amounts of 0.05˜5 wt %, 0.05˜10 wt %, 0.05˜10 wt %, and 0.05˜5 wt %, respectively.

According to the first aspect of the present invention, the present invention provides a method of manufacturing a PCB for a package, comprising (a) providing a printed circuit board for a package with predetermined circuit patterns, having a wire bonding portion and a bump portion for mounting a semiconductor and a soldering portion for connection to external parts; (b) forming a photosolder mask layer to the remaining portions exclusive of at least the bump portion among the wire bonding portion, the bump portion and the soldering portion in the printed circuit board; and (c) forming a tin or tin alloy electroplating layer on any one or more of the wire bonding portion, the bump portion and the soldering portion where the photosolder mask layer is not formed.

According to the second aspect of the present invention, the present invention provides a method of manufacturing a PCB for a package, comprising (a) providing a printed circuit board for a package with predetermined circuit patterns, having a wire bonding portion and a bump portion for mounting a semiconductor and a soldering portion for connection to external parts; (b) forming a photosolder mask layer to the remaining portions exclusive of the wire bonding portion, the bump portion and the soldering portion in the printed circuit board; and (c) forming a tin or tin alloy electroplating layer on the wire bonding portion, the bump portion and the soldering portion.

According to the third aspect of the present invention, the present invention provides a method of manufacturing a PCB for a package, comprising (a) providing a printed circuit board for a package with predetermined circuit patterns, having a wire bonding portion and a bump portion for mounting a semiconductor and a soldering portion for connection to external parts; (b) forming a photosolder mask layer to the remaining portions exclusive of the wire bonding portion, the bump portion and the soldering portion in the printed circuit board; (c) applying a first dry film to the remaining portions exclusive of the wire bonding portion and the soldering portion in the printed circuit board; (d) forming a nickel or nickel alloy electroplating layer on the wire bonding portion and the soldering portion; (e) forming a gold or gold alloy electroplating layer on the nickel or nickel alloy electroplating layer; (f) stripping the first dry film; (g) applying a second dry film to the remaining portions exclusive of the bump portion in the printed circuit board; (h) forming a tin or tin alloy electroplating layer on the bump portion; and (i) stripping the second dry film.

According to the fourth aspect of the present invention, the present invention provides a method of manufacturing a PCB for a package, comprising (a) providing a printed circuit board for a package with predetermined circuit patterns, having a wire bonding portion and a bump portion for mounting a semiconductor and a soldering portion for connection to external parts; (b) forming a photosolder mask layer to the remaining portions exclusive of the wire bonding portion, the bump portion and the soldering portion in the printed circuit board; (c) forming a nickel or nickel alloy electroplating layer on the wire bonding portion, the bump portion, and the soldering portion; (d) forming a gold or gold alloy electroplating layer on the nickel or nickel alloy electroplating layer; (e) applying a dry film to the remaining portions exclusive of the bump portion in the printed circuit board; (f) forming a tin or tin alloy electroplating layer on the bump portion; and (g) stripping the dry film.

As such, the method may further comprise applying a metal mask to the remaining portions exclusive of the bump portion in the PCB, applying a flux on the bump portion and removing the metal mask, subjecting the flux applied bump portion to reflow, and removing the flux.

### BRIEF DESCRIPTION OF THE DRAWINGS

FIG. 1 is cross-sectional views schematically illustrating the process of attaching the bump portion of a die to the bump portion of a PCB according to a conventional flip chip mounting technique;

FIG. 2 is cross-sectional views schematically illustrating the process of attaching the bump portion of a die to the bump portion of a PCB according to another conventional flip chip mounting technique;

FIG. 3 is cross-sectional views schematically illustrating the process of attaching the bump portion of a die to the bump portion of a PCB according to a further conventional flip chip mounting technique;

FIG. 4 is cross-sectional views schematically illustrating the process of attaching the bump portion of a die to the bump portion of a PCB according to a still further conventional flip chip mounting technique;

FIG. 5A is a flowchart illustrating the process of manufacturing a PCB for a package according to an example of a conventional technique;

FIG. 5B is cross-sectional views sequentially illustrating the process of manufacturing a PCB for a package according to the example of a conventional technique;

FIG. 6 is a flowchart and cross-sectional views sequentially illustrating the process of manufacturing a PCB for a package according to a conventional technique;

FIG. 7 is a flowchart and cross-sectional views sequentially illustrating the process of manufacturing a PCB for a package according to a first embodiment of the present invention;

FIG. 8 is a flowchart and cross-sectional views sequentially illustrating the process of manufacturing a PCB for a package according to a second embodiment of the present invention;

FIG. 9 is a flowchart and cross-sectional views sequentially illustrating the process of manufacturing a PCB for a package according to a third embodiment of the present invention; and

FIG. 10 is cross-sectional views schematically illustrating the structures of the plated bump portions in FCCSPs formed according to the embodiments of the present invention.

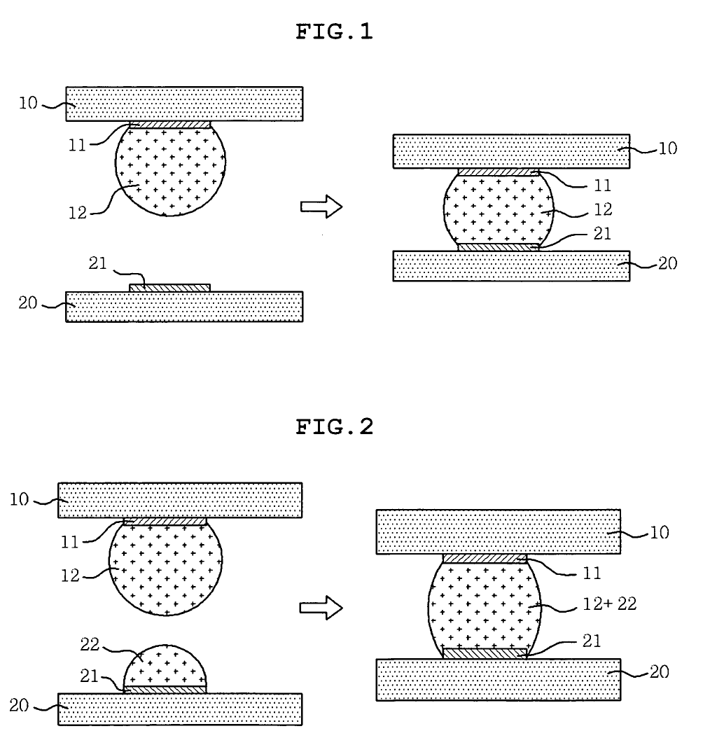

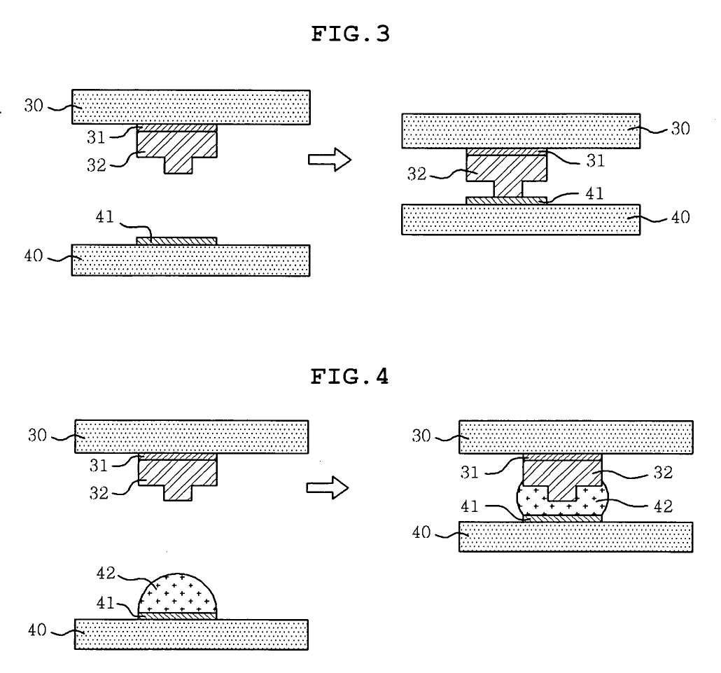

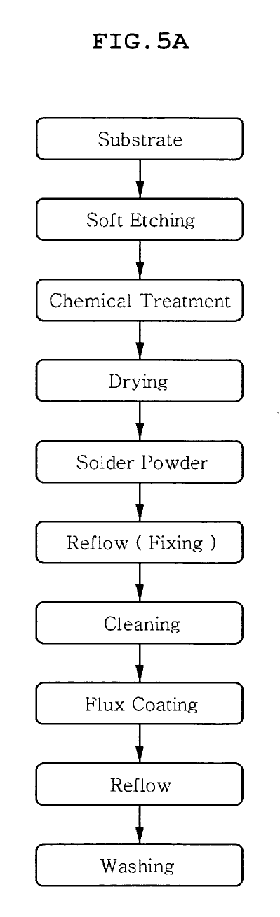

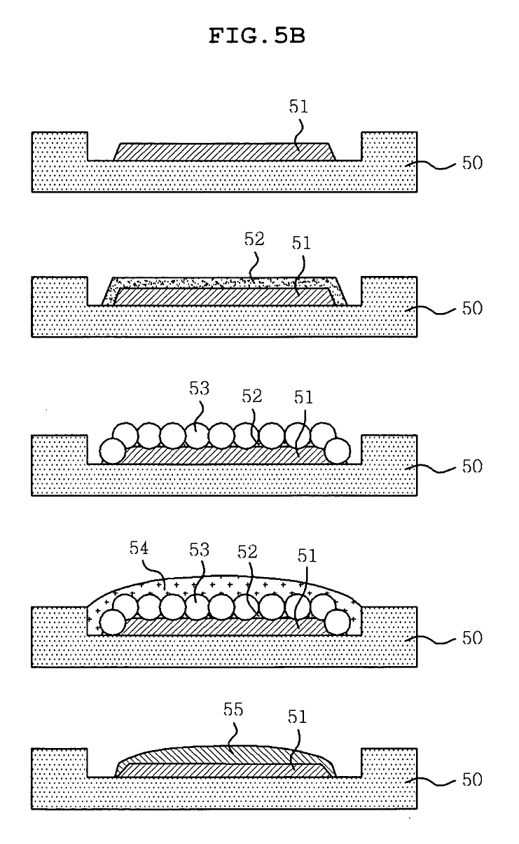

### DESCRIPTION OF THE PREFERRED EMBODIMENTS

Hereinafter, a detailed description will be given of the preferred embodiments of the present invention, with reference to the appended drawings.

In the above-mentioned conventional semiconductor mounting technology, for example, in the flip chip technology, the connection between the bump portion of the die and the bump portion of the PCB may be realized directly using the solder instead of Au wires, or the die may be directly connected to the PCB via the Au stud formed on the die. However, according to the present invention, a packaging technique for forming a pre-solder on the PCB in order to achieve the connection between the die and the PCB is provided, and has the following advantages.

First, the solder is formed on the PCB so as to assure a necessary amount of solder. The solder, which is a factor for maintaining the gap between the PCB and the die, should be sufficiently high to be suitable for underfilling between the PCB and the die. In conventional techniques, because the solder or under bump metal (UBM) is formed only on the die, the volume is limited and a high manufacturing cost is incurred.

Second, in the case where the die is attached to the PCB using an Au stud formed on the die in the absence of a pre-solder on the PCB according to a conventional technique, adhesion between the die and the PCB is poor. As such, an attachment process further requires high heat. For these reasons, the process of forming the pre-solder on the PCB according to the present invention is distinguished from the process of forming the bump (e.g., UBM) on the chip die, that is, the wafer.

Accordingly, the present invention is characterized in that a pre-solder is formed using an electroplating process based on such flip chip technology.

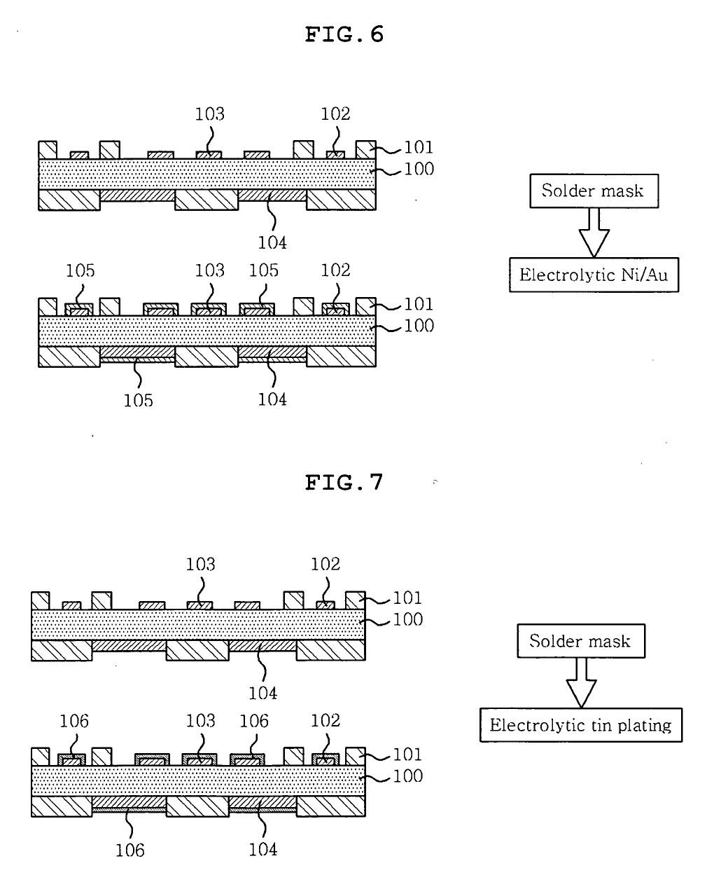

FIGS. 6 and 7 schematically illustrate the process of manufacturing a PCB for a package according to a conventional technique and the present invention, respectively.

In FIG. 6, a photosolder mask 101 is applied to the remaining portions exclusive of a wire bonding portion 102 for mounting a semiconductor, a bump portion 103 therefor, and a soldering portion 104 for connection to external parts, according to a typical CSP process in a PCB 100. The wire bonding portion 102, the bump portion 103, and the soldering portion 104 are subjected to nickel/gold electroplating to thus form a Ni/Au electroplating layer 105.

Although the process of FIG. 7 is similar to the above CSP process, it is different therefrom in that a tin or tin alloy electroplating layer 106 instead of the Ni/Au electroplating layer 105 is formed on a wire bonding portion 102, a bump portion 103 and a soldering portion 104.

The tin alloy electroplating layer may comprise tin (Sn) and any one selected from among silver (Ag), copper (Cu), zinc (Zn), bismuth (Bi), and combinations thereof. Preferably, the tin alloy electroplating layer is composed of Sn—Ag, Sn—Cu, Sn—Zn, or Sn—Bi. In the tin alloy electroplating layer, when Ag, Cu, Zn, and Bi are used in amounts of 0.05˜5 wt %, 0.05˜10 wt %, 0.05˜10 wt %, and 0.05˜5 wt %, respectively, it is easy to control a plating solution and to adjust the amount of components when electroplating. Further, when attaching the chip die to the PCB, a layer of IMC (InterMetallic Compound) having good adhesion is preferably formed.

The tin electroplating process or tin alloy electroplating process is performed at 20˜45° C. for 5˜60 min at a current density of 0.1˜5 A/dm² (ASD), in order to obtain a predetermined plating thickness.

It is preferred that the thickness of the tin or tin alloy electroplating layer thus obtained be 0.05˜20 μm. The reason is that the amount of solder suitable for connection between the chip die and the PCB may be assured to thus increase adhesion therebetween, and also that the gap between the chip die and the PCB may be appropriately maintained so as not to generate voids upon the application of a resin for protection of the connection state between the chip die and the PCB, thereby solving the problem of poor reliability due to the voids.

The PCB for a package thus obtained may have a pre-solder formed through a sequence of applying a metal mask to the remaining portions exclusive of the bump portion in the PCB, removing the metal mask, performing a reflow process, and removing a flux, at an appropriate time before attachment to the die depending on the type of product thereof.

As such, although the thickness of the metal mask varies depending on the type of product, the metal mask is preferably applied to a thickness of about 40˜150 μm without particular limitation. Further, the bump portion is preferably opened by the metal mask within a distance of about 1000 μm from the tin plated portion. The reflow process for sufficiently melting the tin plating material to be recrystallized is performed using N₂ purging gas and O₂ of 300 ppm or less under temperature and time conditions of 80˜180° C. and 60˜150 sec in a preheating zone, 231° C. or higher and 40˜80 sec in a dwell zone, and 255±15° C. in a peak zone, but the present invention is not limited thereto.

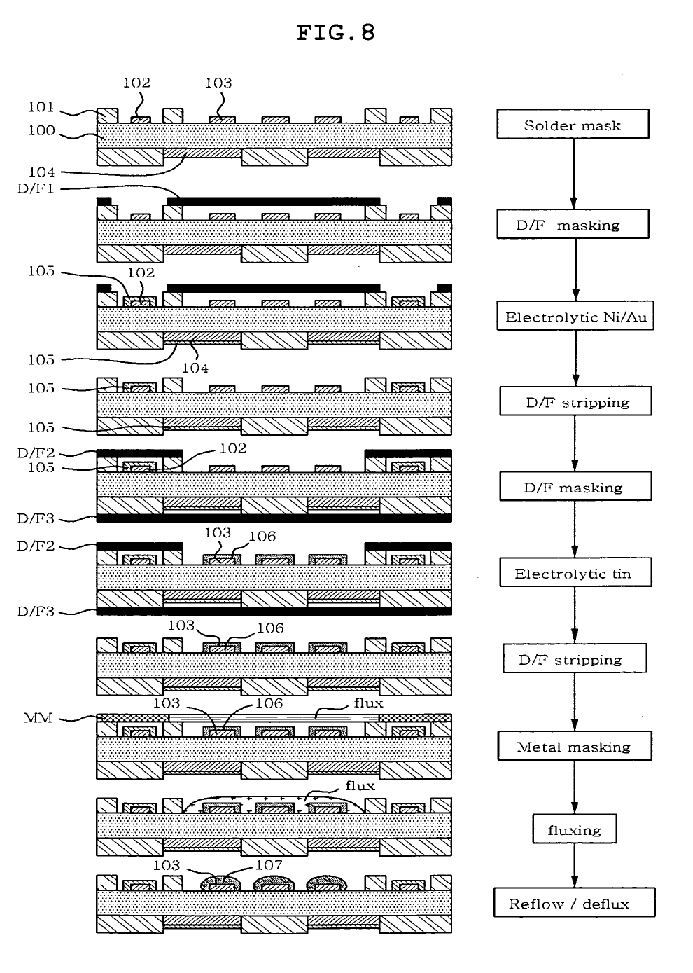

FIG. 8 illustrates the process of manufacturing a PCB for a package according to a second embodiment of the present invention for an FCCSP design having both a general electrolytic Ni/Au pad for wire bonding and an electrolytic tin pad having tin or tin alloy directly plated on Cu of a bump pad.

As shown in FIG. 8, a photosolder mask 101 is applied to the remaining portions exclusive of a wire bonding portion 102, a bump portion 103, and a soldering portion 104 in a PCB 100, after which a dry film D/F1 is applied to the remaining portions exclusive of the wire bonding portion 102 and the soldering portion 104, to thus mask it.

Subsequently, an Ni/Au electroplating layer 105 is formed on the wire bonding portion 102 and the soldering portion 104 through a typical nickel/gold electroplating process, and then the dry film D/F1 is stripped.

As such, the nickel plating layer or the nickel alloy plating layer is 2˜20 μm thick, and the gold plating layer or the gold alloy plating layer is 0.03˜1.5 μm thick.

Thereafter, dry films D/F2, D/F3 are applied to the remaining portions exclusive of the bump portion 103 in the PCB to thus mask them, and a tin or tin alloy electroplating layer 106 is formed on the bump portion 103 through a tin or tin alloy electroplating process, followed by stripping the dry films D/F2, D/F3.

The composition of the tin alloy plating layer 106 and the conditions for the tin or tin alloy electroplating process are as mentioned in FIG. 7.

The PCB for a package thus obtained may have a pre-solder formed through a sequence of applying a metal mask MM to the remaining portions exclusive of the bump portion 103 in the PCB, applying a flux on the tin alloy plating layer 106, removing the metal mask MM, and performing a reflow process for heat treatment to recrystallize tin and increase the height of the pre-solder 107 at an appropriate time before attachment to the die depending on the type of product thereof. After the reflow process, the flux is removed.

In particular, after the Ni/Au electroplating process is performed on the soldering portion in a ball side and the wire bonding portion in a bumping side, on which a recognizable mark and a wire bonding pad are present, and the tin electroplating process is performed on Cu of the bump pad of the bumping side, steps of opening only the tin-plated portion using a metal mask, applying the flux, performing reflow at an appropriate temperature, and performing cleaning are carried out, thus forming a pre-solder suitable for the Au stud bump of the die of the FCCSP.

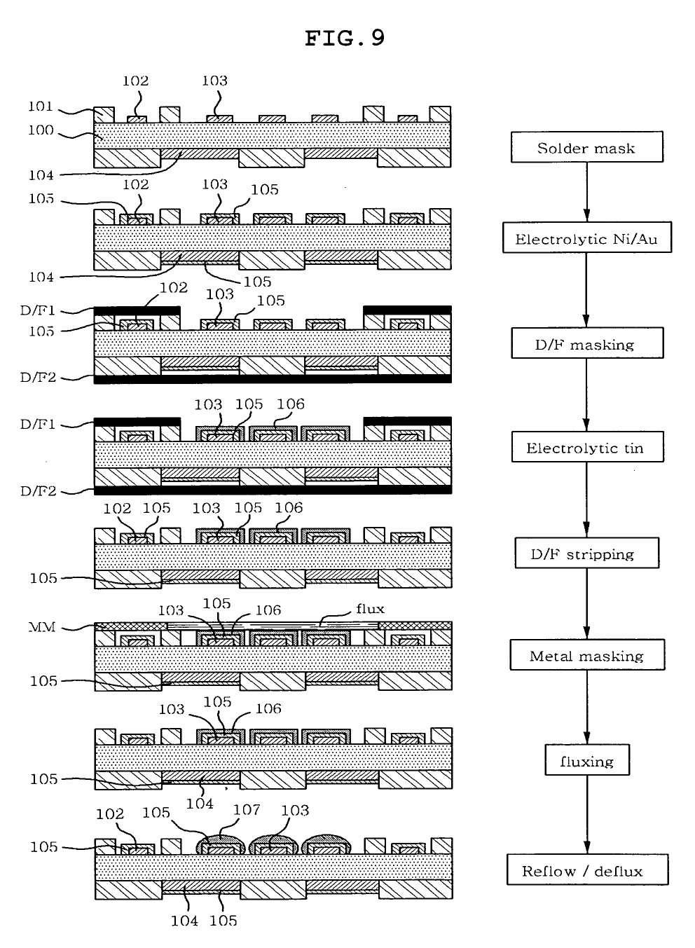

FIG. 9 illustrates the process of manufacturing a PCB for a package according to a third embodiment of the present invention for an FCCSP design in which all of the wire bonding portion, the bump portion, and the soldering portion are electroplated with Ni/Au and then only the bump portion is additionally electroplated with tin or tin alloy, unlike the process of FIG. 8.

As shown in FIG. 9, a photosolder mask 101 is applied to the remaining portions exclusive of a wire bonding portion 102, a bump portion 103, and a soldering portion 104 in a PCB 100, after which an Ni/Au electroplating layer 105 is formed on the wire bonding portion 102, the bump portion 103, and the soldering portion 104 through a typical nickel/gold electroplating process.

As such, it is preferred that the thickness of the nickel electroplating layer or the nickel alloy electroplating layer be 0.05˜5 μm and that the thickness of the gold electroplating layer or the gold alloy electroplating layer be 0.03˜1.5 μm, but the present invention is not limited thereto. This is because a decrease in circuit width due to drastic diffusion of Cu upon the formation of an IMC layer for connection between the chip die and the PCB may be prevented to thus maintain an appropriate circuit width, and because it is possible to realize fine bumps.

Subsequently, dry films D/F1, D/F2 are applied to the remaining portions exclusive of the bump portion 103 in the PCB to thus mask them, and a tin electroplating layer or a tin alloy electroplating layer 106 is formed on the bump portion 103 through a tin or tin alloy electroplating process, after which the dry films D/F1, D/F2 are stripped.

The composition of the tin alloy electroplating layer 106 and the conditions for the tin or tin alloy electroplating process are as mentioned in FIG. 7.

The PCB for a package thus obtained may have a pre-solder formed through a sequence of applying a metal mask MM to the remaining portions exclusive of the bump portion 103 in the PCB, applying a flux on the bump portion 103, removing the metal mask MM, and performing a reflow process for heat treatment to re-crystallize tin and increase the height of the pre-solder 107, at an appropriate time before attachment to the die depending on the type of product thereof. After the reflow process, the flux is removed. That is, only the tin plated portion 103 is opened by the metal mask, and applying the flux, performing reflow at an appropriate temperature, and performing cleaning are carried out to thus form a pre-solder suitable for the Au stud bump of the die of the FCCSP.

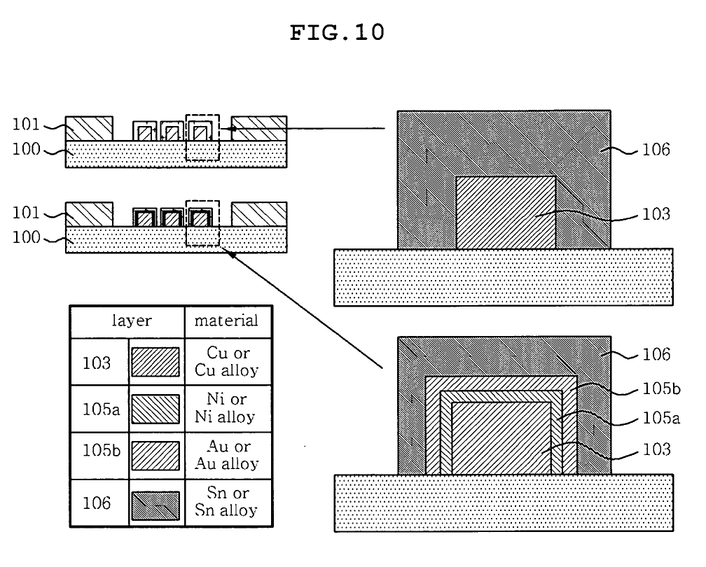

Turning now to FIG. 10, the structures of the plated bump portions in the FCCSPs formed according to the preferred embodiments of the present invention are shown.

The structure of the plated bump portion of the PCB manufactured using the process of FIGS. 7 and 8 includes a copper circuit, that is, a copper layer or a copper alloy layer 103 and a tin electroplating layer or a tin alloy electroplating layer 106 directly formed thereon, as illustrated in the top portion of FIG. 10.

On the other hand, the structure of the plated bump portion of the PCB manufactured using the process of FIG. 9 includes a copper circuit, that is, a copper layer or a copper alloy layer 103, an Ni or Ni alloy electroplating layer 105a, an Au or Au alloy electroplating layer 105b, and a tin or tin alloy electroplating layer 106, which are sequentially formed as illustrated in the bottom portion of FIG. 10.

A better understanding of the present invention may be obtained in light of the following examples, which are set forth to illustrate, but are not to be construed to limit the present invention.

### EXAMPLE 1

In the product as in FIG. 7, all of a soldering portion, a bump portion, and a wire bonding portion having a mark recognizable to a camera and a mold gate for molding after mounting were subjected to tin plating. In particular, the pitch of the bump portion was set within a range of 40˜200 μm, and the thickness of the plating layer was changed depending on the pitch. In the present example, in the case of 100 μm pitch, since a bump copper circuit interval was small, in the vicinity of about 30 μm, the tin plating was performed to a target thickness of 10 μm. To this end, using a PC-MT plating solution available from Incheon Chemical, Korea, the plating process was performed at 25° C. for 25 min at 1.0 ASD, resulting in a plating layer composed of at least 99% pure tin. Additionally, the plating process was conducted at 25° C. for 12 min at 3 ASD using a UTB-TS 140 plating solution, available from Ishihara Chemical, Japan, resulting in a plating layer composed of 97.5% Sn and 2.5% Ag. Upon attachment of the PCB thus manufactured to the chip die, a typical flip chip process for a stud bump was applied. Further, in order to protect the gap between the chip die and the PCB, it was possible to typically use NCP, NCF, ACF, ACP, or underfill paste. In the present example, an underfill paste was used for mounting.

### EXAMPLE 2

In the product as in FIG. 8, among a soldering portion, a bump portion, and a wire bonding portion having a mark recognizable to a camera and a mold gate for molding after mounting, only the bump portion was subjected to tin plating. The copper pads, other than the bump portion, were subjected to nickel and gold plating. As such, the bump portion was masked with a dry film so as not to be plated. Subsequently, when the bump portion was subjected to tin plating, the portion of the substrate other than the bump portion was masked with a dry film such that the nickel and gold plated portion was not plated with tin. The thickness of the nickel plating layer was 2˜20 μm, which was as thick as a general nickel electroplating layer. In particular, the pitch of the bump portion was set within a range of 40˜200 μm, and the thickness of the plating layer was changed depending on the pitch. In the present example, in the case of 100 μm pitch, since a bump copper circuit interval was small, in the vicinity of about 30 μm, the tin plating was performed to a target thickness of 10 μm. To this end, using a PC-MT plating solution available from Incheon Chemical, Korea, the plating process was performed at 25° C. for 25 min at 1.0 ASD, resulting in a plating layer composed of at least 99% pure tin. Additionally, the plating process was conducted at 25° C. for 12 min at 3 ASD using a UTB-TS 140 plating solution available from Ishihara Chemical, Japan, resulting in a plating layer composed of 97.5% Sn and 2.5% Ag. Then, a 120 μm thick metal mask formed of nickel or SUS was applied to the remaining portions exclusive of the tin plated bump portion in the PCB so that the bump portion was opened at a distance of 700 μm therefrom, after which a flux was applied on the opened bump portion. Subsequently, a reflow process was performed using N₂ purging gas and O₂ in an amount of 300 ppm or less under temperature and time conditions of 80˜180° C. and 60˜150 sec in a preheating zone, 231° C. or higher and 40˜80 sec in a dwell zone, and 255±15° C. in a peak zone, to thus recrystallize the plated tin and double the height of the pre-solder. Thereafter, a deflux process for removing the residual flux was performed, thereby completing a PCB. The attachment of the PCB thus manufactured to the chip die was conducted according to a typical flip chip process for a stud bump. In order to protect the gap between the chip die and the PCB, an underfill paste was used for mounting.

### EXAMPLE 3

In the product as in FIG. 9, among a soldering portion, a bump portion, and a wire bonding portion having a mark recognizable to a camera and a mold gate for molding after mounting, only the bump portion was subjected to tin plating. All the copper pads were subjected to nickel and gold plating. Subsequently, when the bump portion was subjected to tin plating, part of the substrate other than the bump portion was masked with a dry film such that a nickel and gold plating layer and then a tin plating layer were formed only on the bump portion. In particular, the pitch of the bump portion was set within a range of 40˜200 μm, and the thickness of the plating layer was changed depending on the pitch. In the present example, in the case of 100 μm pitch, since a bump copper circuit interval was small, in the vicinity of about 30 μm, the nickel plating layer was formed to a thickness of 1.0 μm, which was less than the thickness of a general nickel electroplating layer. Further, the tin plating was performed to a target thickness of 10 μm. To this end, using a PC-MT plating solution, available from Incheon Chemical, Korea, the plating process was performed at 25° C. for 25 min at 1.0 ASD, resulting in a plating layer formed of at least 99% pure tin. Additionally, the plating process was conducted at 25° C. for 12 min at 3 ASD using a UTB-TS 140 plating solution available from Ishihara Chemical, Japan, resulting in a plating layer formed of 97.5% Sn and 2.5% Ag. Then, a 120 μm thick metal mask formed of nickel or SUS was applied on part of the substrate other than the tin plated bump portion so that the bump portion was opened at a distance of 700 μm therefrom, after which a flux was applied on the bump portion thus opened. Subsequently, a reflow process was performed using N₂ purging gas and O₂ of 300 ppm or less under temperature and time conditions of 80˜180° C. and 60˜150 sec in a preheating zone, 231° C. or higher and 40˜80 sec in a dwell zone, and 255±15° C. in a peak zone, to thus recrystallize the plated tin and double the height of the pre-solder. Thereafter, a deflux process for removing the residual flux was performed, thereby completing a PCB. The attachment of the PCB thus manufactured to the chip die was conducted according to a typical flip chip process for a stud bump. In order to protect the gap between the chip die and the PCB, an underfill paste was used for mounting.

### COMPARATIVE EXAMPLE 1

In the product as in FIG. 6, all of a soldering portion, a bump portion, and a wire bonding portion having a mark recognizable to a camera and a mold gate for molding after mounting were subjected to nickel and gold plating. However, the nickel and gold plating process could not be applied to products of 100 μm pitch or less due to the difficulty in controlling the plating thickness. Thus, in the case of 200 μm pitch, since a bump copper circuit interval was about 50 μm, the nickel plating was performed to a target thickness of 10 μm. To this end, the nickel plating was performed at 50° C. for 25 min at 1.2 ASD using a nickel sulfamate plating solution, available from Nippon Chemical, after which the gold plating process was performed at 40° C. for 1 min at 0.3 ASD using a TEMPERST EX plating solution, available from Japan Pure Chemical, to thus form a 0.05 μm thick layer and then at 70° C. for 7 min at 0.17 ASD to thus form a 0.5 μm thick layer. The attachment of the PCB thus manufactured to the chip die was conducted according to a typical flip chip process for a stud bump, and an underfill paste was used for mounting.

The plated structure and the plated surface state of the bumping side and ball side of each of the FCCSP products manufactured in Examples 1˜3 and Comparative Example 1 are summarized in Table 1 below.

TABLE 1

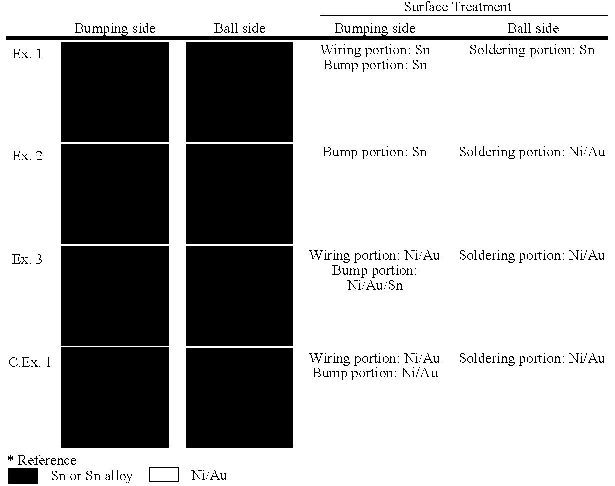

*Even when each of Ni, Au, and Sn shown in Table 1 is alloyed, it is briefly represented by Ni, Au, Sn.

The reliability for bondability and underfilling capability upon connection between the chip die and the PCB was evaluated after mounting using Precon (preconditioning), TC (Temperature Cycling) and PCT (Press Cooker Test) methods. As such, when bondability was determined to be poor, cracks were generated at the connection surface to thus undesirably result in poor open defects, and poor underfilling capability led to the generation of voids. Upon the evaluation of reliability, such voids could be enlarged or delamination could occur, undesirably causing open or short defects. The results of the examples and comparative example are given in Table 2 below. The conditions for evaluation of reliability were as follows.

A Precon method was conducted under conditions of temperature cycling of −40° C. (15 min)˜60° C. (15 min) for 5 cycles, baking at 125° C. (+5/0) min 24 hr, moisture soak 60° C./60% 120 hr, and IR reflow 260° C. for 3 cycles, a TC method under conditions of −55° C. (15 min)˜125° C. (15 min) for 1000 cycles, and a PCT method under conditions of 121° C., 100RH %, 2 atm and 168 hr.

TABLE 2

| | | Underfilling | |
|---|---|---|---|
| | Bondability | Capability | Note |
| Ex. 1 | Very Good | Good | Pre-Solder |
| Ex. 2 | Very Good | Good | Pre-Solder |
| Ex. 3 | Very Good | Good | Pre-Solder |
| C. Ex. 1 | Average | Average | No Pre-Solder |

Although the preferred embodiments of the present invention relating to the PCB for a package and the manufacturing method thereof have been disclosed for illustrative purposes, those skilled in the art will appreciate that various modifications, additions and substitutions are possible, without departing from the technical spirit of the invention.

As described hereinbefore, among conventional pre-solder formation techniques, a screen printing method cannot be applied to a pre-solder (bump) of 120 μm pitch or less, and a super juffit method and a super solder method using solder paste or solder powder suffer because it is difficult to use them to control the height of the pre-solder, and they incur high costs.

However, according to the present invention, in the case where a pre-solder is formed by reflow using an electroplating process, it may be imparted with a desired thickness via control of a plating thickness in the presence of a bus line on a PCB. In addition, such a solder may be applied to a fine pitch through a masking process.

Further, in the case where a tin or tin alloy electroplating process is performed on a typical Ni/Au layer according to a preferred embodiment of the present invention, the thickness of Ni is controlled to be low and thus drastic Cu loss of a bump pad may be prevented by the Ni layer acting as a barrier upon formation of IMC through reflow after tin plating. Also, the pre-solder may correspond to a fine bump pitch thanks to the thin Ni. In addition, according to another preferred embodiment of the present invention, in the case where the tin or tin alloy electroplating layer is directly formed on the bump portion, the total manufacturing process and cost are decreased by virtue of the simple process.

In the present invention, when the pre-solder is formed using a tin or tin alloy plating process, it is easy to increase the height of the pre-solder and to uniformly control the thickness thereof. Therefore, the pre-solder is formed on the bump pad of the FCCSP product through tin plating, thereby enhancing bondability and underfilling capability between the bump of a die, such as a stud bump, and the PCB.

Simple modifications to and variations in the present invention belong within the scope of the present invention, and the specific scope thereof will become definite with reference to the appended claims.

What is claimed is:

1. A printed circuit board for a package with predetermined circuit patterns, having a wire bonding portion and a bump portion for mounting a semiconductor and a soldering portion for connection to external parts;
wherein at least the bump portion among the wire bonding portion, the bump portion and the soldering portion includes:
a copper or copper alloy layer; and
a tin or tin alloy electroplating layer formed on the copper or copper alloy layer.

2. The printed circuit board as set forth in claim 1, wherein the tin alloy electroplating layer comprises tin (Sn) and any one selected from among silver (Ag), copper (Cu), zinc (Zn), bismuth (Bi), and combinations thereof.

3. The printed circuit board as set forth in claim 2, wherein the tin alloy electroplating layer comprises Sn—Ag, Sn—Cu, Sn—Zn, or Sn—Bi, and Ag, Cu, Zn and Bi in the tin alloy electroplating layer are used in amounts of 0.05˜5 wt %, 0.05˜10 wt %, 0.05˜10 wt %, and 0.05˜5 wt %, respectively.

4. A printed circuit board for a package with predetermined circuit patterns, having a wire bonding portion and a bump portion for mounting a semiconductor and a soldering portion for connection to external parts;
wherein the wire bonding portion, the bump portion and the soldering portion include:
a copper or copper alloy layer; and
a tin or tin alloy electroplating layer formed on the copper or copper alloy layer.

5. The printed circuit board as set forth in claim 4, wherein the tin alloy electroplating layer comprises tin (Sn) and any one selected from among silver (Ag), copper (Cu), zinc (Zn), bismuth (Bi), and combinations thereof.

6. The printed circuit board as set forth in claim 5, wherein the tin alloy electroplating layer comprises Sn—Ag, Sn—Cu, Sn—Zn, or Sn—Bi, and Ag, Cu, Zn and Bi in the tin alloy electroplating layer are used in amounts of 0.05˜5 wt %, 0.05˜10 wt %, 0.05˜10 wt %, and 0.05˜5 wt %, respectively.

7. A printed circuit board for a package with predetermined circuit patterns, having a wire bonding portion and a bump portion for mounting a semiconductor and a soldering portion for connection to external parts;
wherein the wire bonding portion and the soldering portion include:
a copper or copper alloy layer;
a nickel or nickel alloy electroplating layer formed on the copper or copper alloy layer; and
a gold or gold alloy electroplating layer formed on the nickel or nickel alloy electroplating layer, and
the bump portion includes:
a copper or copper alloy layer; and
a tin or tin alloy electroplating layer formed on the copper or copper alloy layer.

8. The printed circuit board as set forth in claim 7, wherein the tin alloy electroplating layer comprises tin (Sn) and any one selected from among silver (Ag), copper (Cu), zinc (Zn), bismuth (Bi), and combinations thereof.

9. The printed circuit board as set forth in claim 8, wherein the tin alloy electroplating layer comprises Sn—Ag, Sn—Cu, Sn—Zn, or Sn—Bi, and Ag, Cu, Zn and Bi in the tin alloy electroplating layer are used in amounts of 0.05˜5 wt %, 0.05˜10 wt %, 0.05˜10 wt %, and 0.05˜5 wt %, respectively.

10. A printed circuit board for a package with predetermined circuit patterns, having a wire bonding portion and a bump portion for mounting a semiconductor and a soldering portion for connection to external parts;
wherein the wire bonding portion and the soldering portion include:
a copper or copper alloy layer;
a nickel or nickel alloy electroplating layer formed on the copper or copper alloy layer; and
a gold or gold alloy electroplating layer formed on the nickel or nickel alloy electroplating layer, and
the bump portion includes:
a copper or copper alloy layer;
a nickel or nickel alloy electroplating layer formed on the copper or copper alloy layer;
a gold or gold alloy electroplating layer formed on the nickel or nickel alloy electroplating layer; and
a tin or tin alloy electroplating layer formed on the gold or gold alloy electroplating layer.

11. The printed circuit board as set forth in claim 10, wherein the tin alloy electroplating layer comprises tin (Sn) and any one selected from among silver (Ag), copper (Cu), zinc (Zn), bismuth (Bi), and combinations thereof.

12. The printed circuit board as set forth in claim 11, wherein the tin alloy electroplating layer comprises Sn—Ag, Sn—Cu, Sn—Zn, or Sn—Bi, and Ag, Cu, Zn and Bi in the tin alloy electroplating layer are used in amounts of 0.05˜5 wt %, 0.05˜10 wt %, 0.05˜10 wt %, and 0.05˜5 wt %, respectively.

13. A method of manufacturing a printed circuit board for a package, comprising:
(a) providing a printed circuit board for a package with predetermined circuit patterns, having a wire bonding portion and a bump portion for mounting a semiconductor and a soldering portion for connection to external parts;
(b) forming a photosolder mask layer to the remaining portions exclusive of at least the bump portion among the wire bonding portion, the bump portion and the soldering portion in the printed circuit board; and
(c) forming a tin or tin alloy electroplating layer on any one or more of the wire bonding portion, the bump portion and the soldering portion where the photosolder mask layer is not formed.

14. The method as set forth in claim 13, further comprising applying a metal mask to the remaining portions exclusive of the bump portion in the printed circuit board, applying a flux on the bump portion and removing the metal mask, and subjecting the flux applied bump portion to reflow.

15. The method as set forth in claim 13, wherein the tin alloy electroplating layer comprises tin (Sn) and any one selected from among silver (Ag), copper (Cu), zinc (Zn), bismuth (Bi), and combinations thereof.

16. The method as set forth in claim 15, wherein the tin alloy electroplating layer comprises Sn—Ag, Sn—Cu, Sn—Zn, or Sn—Bi, and Ag, Cu, Zn and Bi in the tin alloy electroplating layer are used in amounts of 0.05˜5 wt %, 0.05˜10 wt %, 0.05˜10 wt %, and 0.05˜5 wt %, respectively.

17. A method of manufacturing a printed circuit board for a package, comprising:
(a) providing a printed circuit board for a package with predetermined circuit patterns, having a wire bonding portion and a bump portion for mounting a semiconductor and a soldering portion for connection to external parts;
(b) forming a photosolder mask layer to the remaining portions exclusive of the wire bonding portion, the bump portion and the soldering portion in the printed circuit board; and
(c) forming a tin or tin alloy electroplating layer on the wire bonding portion, the bump portion and the soldering portion.

18. The method as set forth in claim 17, further comprising applying a metal mask to the remaining portions exclusive of the bump portion in the printed circuit board, applying a flux on the bump portion and removing the metal mask, and subjecting the flux applied bump portion to reflow.

19. The method as set forth in claim 17, wherein the tin alloy electroplating layer comprises tin (Sn) and any one selected from among silver (Ag), copper (Cu), zinc (Zn), bismuth (Bi), and combinations thereof.

20. The method as set forth in claim 19, wherein the tin alloy electroplating layer comprises Sn—Ag, Sn—Cu, Sn—Zn, or Sn—Bi, and Ag, Cu, Zn and Bi in the tin alloy electroplating layer are used in amounts of 0.05˜5 wt %, 0.05˜10 wt %, 0.05˜10 wt %, and 0.05˜5 wt %, respectively.

21. A method of manufacturing a printed circuit board for a package, comprising:
(a) providing a printed circuit board for a package with predetermined circuit patterns, having a wire bonding portion and a bump portion for mounting a semiconductor and a soldering portion for connection to external parts;
(b) forming a photosolder mask layer to the remaining portions exclusive of the wire bonding portion, the bump portion and the soldering portion in the printed circuit board;
(c) applying a first dry film to the remaining portions exclusive of the wire bonding portion and the soldering portion in the printed circuit board;
(d) forming a nickel or nickel alloy electroplating layer on the wire bonding portion and the soldering portion;
(e) forming a gold or gold alloy electroplating layer on the nickel or nickel alloy electroplating layer;
(f) stripping the first dry film;
(g) applying a second dry film to the remaining portions exclusive of the bump portion in the printed circuit board;
(h) forming a tin or tin alloy electroplating layer on the bump portion; and
(i) stripping the second dry film.

22. The method as set forth in claim 21, further comprising applying a metal mask to the remaining portions exclusive of the bump portion in the printed circuit board, applying a flux on the bump portion and removing the metal mask, and subjecting the flux applied bump portion to reflow.

23. The method as set forth in claim 21, wherein the tin alloy electroplating layer comprises tin (Sn) and any one selected from among silver (Ag), copper (Cu), zinc (Zn), bismuth (Bi), and combinations thereof.

24. The method as set forth in claim 23, wherein the tin alloy electroplating layer comprises Sn—Ag, Sn—Cu, Sn—Zn, or Sn—Bi, and Ag, Cu, Zn and Bi in the tin alloy electroplating layer are used in amounts of 0.05˜5 wt %, 0.05˜10 wt %, 0.05˜10 wt %, and 0.05˜5 wt %, respectively.

25. A method of manufacturing a printed circuit board for a package, comprising:
(a) providing a printed circuit board for a package with predetermined circuit patterns, having a wire bonding portion and a bump portion for mounting a semiconductor and a soldering portion for connection to external parts;
(b) forming a photosolder mask layer to the remaining portions exclusive of the wire bonding portion, the bump portion and the soldering portion in the printed circuit board;
(c) forming a nickel or nickel alloy electroplating layer on the wire bonding portion, the bump portion, and the soldering portion;
(d) forming a gold or gold alloy electroplating layer on the nickel or nickel alloy electroplating layer;
(e) applying a dry film to the remaining portions exclusive of the bump portion in the printed circuit board;
(f) forming a tin or tin alloy electroplating layer on the bump portion; and
(g) stripping the dry film.

26. The method as set forth in claim 25, further comprising applying a metal mask to the remaining portions exclusive of the bump portion in the printed circuit board, applying a flux on the bump portion and removing the metal mask, and subjecting the flux applied bump portion to reflow.

27. The method as set forth in claim 25, wherein the tin alloy electroplating layer comprises tin (Sn) and any one selected from among silver (Ag), copper (Cu), zinc (Zn), bismuth (Bi), and combinations thereof.

28. The method as set forth in claim 27, wherein the tin alloy electroplating layer comprises Sn—Ag, Sn—Cu, Sn—Zn, or Sn—Bi, and Ag, Cu, Zn and Bi in the tin alloy electroplating layer are used in amounts of 0.05˜5 wt %, 0.05˜10 wt %, 0.05˜10 wt %, and 0.05˜5 wt %, respectively.
